(19) United States
(12) Patent Application Publication
(10) Pub. No.: US 2005/0190094 A1
(43) Pub. Date: Sep. 1, 2005

(54) Method for measuring currents in a motor controller and motor controller using such method

(75) Inventor: Henrik Rosendal Andersen, Graasten (DK)

Correspondence Address: MCCORMICK, PAULDING & HUBER LLP, CITY PLACE II, 185 ASYLUM STREET, HARTFORD, CT, 06103, US

(73) Assignee: Danfoss Drives A/S, Graasten (DK)

(21) Appl. No.: 10/511,462

(22) PCT Filed: Apr. 11, 2003
(86) PCT No.: PCT/DK03/00243

§ 371 Date: Apr. 11, 2005

(30) Foreign Application Priority Data
Apr. 17, 2002 (DK) PA200200572

(51) Int. Cl. H03M 1/60

(52) U.S. Cl. 341/157

(57) ABSTRACT

The invention relates to a method for measuring currents in a motor controller. Some current sensing devices placed on the motor wires or inside the motor controller provide low amplitude output signals thus complicating sampling and data processing. In order to improve the signal/noise ratio, an oversampling technique is disclosed which makes used of a differential transmission of the output signal. Further, by applying intelligent sorting techniques on the sampled data, a substantial improvement in the signal/noise ratio can be obtained. The invention also concerns a motor controller using this method, and discloses the use of a power card and a control card, where the current sensing device is placed on the power card and a differential amplifier is placed on the control card. The gain of the differential amplifier is controlled by components placed on the power card as well as on the control card.

### CROSS-REFERENCE TO RELATED APPLICATIONS

This application is entitled to the benefit of and incorporates by reference essential subject matter disclosed in International Application No. PCT/DK03/00243 filed on Apr. 11, 2003 and Danish Patent Application-No. PA—2002 00572 filed on Apr. 17, 2002.

### FIELD OF THE INVENTION

The invention concerns a method for measuring currents in a motor controller and a motor controller using this method. By way of example such motor controllers are frequency converters or servo drives.

### BACKGROUND OF THE INVENTION

A standard PWM (pulse-width-modulation) motor controller normally includes a control card and a power card. The control card is typically a power invariant unit which is used over the power range of a motor controller series. The power card is by nature a function of the power size meaning that variance in a converter series should be placed here. The control card includes the digital processing unit for controlling the converter, e.g. a DSP (Digital Signal Processor), a microcontroller or an ASIC (Application Specific Integrated Circuit) etc. The control card also includes an A/D-converter and conditioning circuits. The control card is connected to the power card via a parallel connector handling all interface signals. The signals range from digital signals over analog signals such as supply voltages and references to sensing signals. The power card includes the power electronics such as power transistors and power diodes, gate drives, electrolytic capacitors, inductors, a switched-mode-power-supply (SMPS), filters and sensing circuitry. The current sensing on the power card is a vital part of the motor controller considering the control and protection quality. The power card may include a plurality of current sensors either positioned on the output phases of the motor controller or in the intermediate circuit of the motor controller.

One current sensing technique employs a measuring shunt/resistor and a single amplifier stage for conditioning the signal to e.g. the voltage level of an A/D-converter. This technique is inexpensive and very accurate. But when galvanic isolation is required between the power and the control circuitry, the complexity and price tend to increase while the accuracy decreases. Further, the power loss of shunts normally goes too high when the current range increases above a certain level.

Another more general current sensing technique in standard PWM motor controllers is the use of active magnetic current transducers. Such current transducers are not inserted directly into the conductor but are in principle clamped around the conductor. The current in the conductor generates a magnetic field around the conductor. The field is measured by the current transducer, and the transducer generates a measuring signal proportional to the current in the conductor. The main advantage compared to shunt solutions is that the measuring signal is galvanically isolated while exhibiting an accuracy and a bandwidth, which covers the control and protection demands of standard PWM motor controllers.

Normally the electronics of a current transducer is fed by a bipolar voltage, e.g. +/−15V, but a new unipolar type has emerged, which typically works on a single-sided 5V supply. This type of current transducer is typically ASIC-based. Such unipolar current transducers are suited for the lower current range. 5V sensors may range to 25Arms as competitors to shunts. Unipolar magnetic based current transducers are described in U.S. Pat. No. 5,585,715. The trend towards unipolar current transducers is driven by an urge to simplify the supply circuitry, to reduce its size and to lower the power consumption of the transducer. Lowering the power consumption of the transducer is achieved by the transducer manufacturer by lowering the amplitude of the supply voltage. However, this has led to a problem with the signal/noise ratio (SNR) on the measuring signal. When using a transducer with a bipolar supply of, say, +/−15V, the range of the measuring signal would be about 20V, whereas using a unipolar supply of 5V gives a signal range of 4V or less. Thus, the SNR is lowered by at least a factor five rendering the succeeding signal detection difficult.

A first object of the present invention is to remedy a deterioration in the SNR of the measuring signal caused by a current sensing device or other components used in a motor controller.

A second object is to facilitate the manufacture of variants of motor controllers.

### SUMMARY OF THE INVENTION

The present invention resides in one aspect in a method for measuring currents in a motor controller using switching power semiconductors, where the current is measured by a current sensing device placed on a motor phase and generating an output signal which is transmitted to a receiving unit whereafter the signal is sampled with an oversampling frequency during a switching period of the power semiconductors, said samples being digitally filtered for maintaining symmetry of the samples with respect to a centre line of the switching period, whereafter an average value of the samples is calculated.

In order to optimise the SNR digitally oversampling of the conditioned signal on the control card is used. In a DSP application note from Texas Instruments: “Oversampling strategy on TMS320F240x and C28x”, by Oliver Monnier, 2001, page 1-14, sampling at a frequency significantly above the fundamental frequency of the current to be measured is described. In a known manner, oversampling means sampling with a frequency higher than the Nyquist frequency, i.e. a frequency more than two times the frequency of the signal to be sampled. The application note teaches an improvement in the SNR (quantization noise) by increasing the sampling frequency. Further, to avoid interference on the sampled data from the PWM switching of the PWM inverter, sampling is suggested to be performed in the quiet zone of the PWM switching period of the inverter only, i.e. at a time where the inverter power switches are not switched. Two methods are presented in the note. The first method is not very useful since an evenly distributed sampling over the switching period is omitted. The second method suggests a 256 kHz evenly distributed oversampling strategy within the switching period (16 kHz) with the possibility of delaying some of the sampling incidents if an inverter switching occurs simultaneously with the 256 kHz interrupt. The possible delay is one sample period equal to around 4 μs before conflicting with the next interrupt. This method is applicable for low performance drives but for standard PWM motor controllers with a demand on operating with long motor cables the method exhibits shortcomings.

In the present invention, the “quiet zone” is defined more widely. The quiet zone includes all sources known to disturb the current sensing by utilizing the feedforward knowledge of the control unit to the fullest. As much as possible in the standard PWM motor controller should be controlled by one single control unit. Hence, the quiet PWM zone definition includes the switching incidents of the inverter transistors, the brake transistor in the intermediate circuit of the motor controller and e.g transistors of an active frontend (rectifier, power factor controller). And also important is that the quiet zone of the PWM inverter includes the motor cable ringing period after a switching incident. The switching incident itself may take some hundred nanoseconds whereas the cable ringing period after the switching may easily be 10_s and even more. Now using the inventive method, the A/D-converter is set up to oversample the signal from the current sensing device continuously aiming to get an evenly distributed and even number of samples over a switching period. Preferably, the A/D-converter is synchronized to the switching period.

It should be emphasized that the above sampling method is especially applicable for current sensors on the output phases of the motor controller. The goal being to attenuate random noise by oversampling and averaging, to remove the PWM current ripple of an output phase current, to remove effects from cable ringing and to extract a value for the fundamental output phase current within a switching period referred to the centre line (or start, second average) of the same switching period by loading the control unit to the fullest. Compared to the current in the intermediate circuit, the current on the motor phases is continuous which gives the possibility of applying a very high sampling frequency thus providing much data. With a large amount of data available, it is possible to skip data and still have enough data available to achieve symmetry with respect to the centre line of a switching period.

Thus, the samples taken during a switching period are investigated by the control unit of the motor controller prior to averaging by means of digitally filtering. Such filtering includes sorting and other measures.

Instead of using a sorting process, the A/D-converter could be set up for sampling in a number of precalculated positions within the switching period and then using all samples for the average. The ideal goal is still an even number of evenly distributed samples within the switching period for the average. However, if a sampling instant in the first half of the switching period has to be delayed to ensure a quiet zone sampling, the mirror sampling instant in the second half of the switching period likewise has to be made earlier than intended (hastened) to ensure the same distance to the centre line of the switching period and vice versa. The advantage of the above sorting process is simplicity in implementation according to experience, but since samples are removed the degree of oversampling has to be significant compared to the switching period. The advantage of the A/D-converter programming strategy is that no samples are lost. Instead a cluster of narrow positioned interrupts has to be handled by the controller unit at some instants over the switching period. The average load on the controller unit is however the same compared to sampling with uniform time spacing.

In another embodiment of the invention, sampled data found or supposed to be corrupted are sorted out but in a way, that symmetry of the samples around the centre line of the switching period is maintained. Following this, an average value of the remaining sampled data is calculated. When using long motor cables several current samples in a row after a PWM switching may be corrupted depending on the chosen sampling frequency and the motor cable length.

The sorting process may be optimised for ensuring position symmetry of the remaining number of samples within the switching period. That is, if a sample in the first half of the switching period is sorted out, the mirror of the same sample in the second half of the switching period is sorted out also. Likewise, if a sample in the second half of the switching period is sorted out, the mirror of the same sample in the first half of the switching period is sorted out also. The mirror sample in the second half of the switching period is to be understood as the sample having the same distance to the centre line of the switching period as the sample considered in the first half of the switching period and vice versa. Thus, for each PWM switching period, an averaged and reliable digital current value is made ready and forwarded for further processing. The result is that both the PWM current ripple, effects from cable ringing currents and possible random noise picked up during the transmission of the current transducer signal from the power card to the control card are effectively attenuated giving a robust and noise immune sample of the fundamental output current of the motor controller once per switching period referenced to the centre line of the switching period.

Extending the inventive method to obtain two resulting current samples per switching period for high-performance motor controllers is possible by calculating a second average value from the sum of samples taken from a preceeding switching period and an actual switching period. In particular, such a second average value can be calculated from samples taken in the last half of the preceeding switching period and samples from the first half of the actual switching period. Those skilled in the art will know that this requires that the duty cycles of the PWM inverter do only vary moderately from one PWM period to the next if the second average is to be referred to the start of the actual switching period.

Yet another measure to optimise the SNR is to adapt the oversampling strategy to certain current sensing devices known to produce internal noise on the output. Such devices are magnetic current sensors as mentioned earlier. The internal noise is a result of a trade off from the manufacturer of the current transducer, who minimises the offset drift of the transducer by introducing switching on the magnetic field sensing device within an airgap of the magnetic current transducer. This produces offset ripple on the output signal, and this ripple is additional to the ripple already present on the current to be measured originating from PWM switching. The offset ripple of magnetic current transducers may range to several hundred of kHz. In some cases the offset ripple is more or less white noise, i.e. containing all frequencies, meaning that the best way of attenuating the noise by oversampling is to introduce the fastest sampling frequency possible within the limits of the A/D-converter capacity.

In other cases the offset ripple is at a distinct frequency. Here, the method is to use all resources of the A/D-converter on one current transducer at the time during a start-up initialisation phase of the motor controller with current-free current transducers. In the case, where more than one current transducer is used, the goal is to determine the offset ripple frequency of each current transducer sequentially by oversampling. From this data an optimum sampling frequency may be calculated for the A/D-converter covering all current sensors by the best compromise. Due to the A/D-converter loading during operation of the motor controller it may not be possible to oversample the offset ripple of the current transducers in this case. Undersampling—compared to the frequency of the noise ripple—with an optimum sampling frequency is used instead aiming at attenuating the offset ripple of the current sensors to an acceptable level.

Preferably the output signal is transferred differentially to the receiving unit in order to obtain a higher degree of immunity towards noise.

The objects of the invention are also met with a motor controller which makes use of the method according to claim 1 and which incorporates a power card and a control card, a current sensing device being placed on the power card and an output signal from the sensing device being transmitted to an amplifier placed on the control card. The amplifier for conditioning the current sensing device output is placed on the control card with feedforward and feedback resistors and low-pass filtering in order to enable a minimum distance between the differential amplifier and the A/D-converter. Further, to allow for an adjustable gain and filtering of the measuring signal, a section of extra series-coupled feedforward resistors decoupled to the reference plane by bypass capacitors are placed on the power card near to an interface connector. Thus, the gain and bandwidth setting is distributed between components placed on the power card and on the control card.

A differential transfer of the current sensing device output signal from the power card to the control card enhances the SNR.

Advantageously, the values of the components mounted on the control card are fixed, thus giving the differential amplifier a predetermined gain. However, by changing the values of the components on the power card, variation of motor controllers can be obtained. In other words, a simple and independent gain adjustment for protection and control is made on the power card while a fixed amplifier stage is placed on the control card close to the A/D-converter.

Placing a filter on the power card in the signal path of the current sensing device makes it possible to control the analog filtering degree independent of an internal bandwith of the current sensing device. Such filter may be a lowpass filter having a suitable cut-off frequency.

Advantageously, the current sensing device is a magnetic current transducer being fed with a supply voltage.

Forcing the supply voltage of the magnetic current transducer to be at least two times an internal voltage reference of the transducer enhances the SNR. The information of the magnitude of the internal voltage reference is obtainable from the specifications of the transducer.

A further measure for increasing the SNR is to utilize the supply voltage tolerance of the current transducer to a maximum. Typically, a unipolar current transducer should be fed with 5V+/−5%. This is a known specification for low-voltage electronic equipment in general. 5V -5% will in fact lower the highest possible gain of the current transducer by lowering the positive signal swing range. That is, if the internal reference voltage is 2.5 V the signal swing is from, let us say, 4.5 to 0.5V assuming that the sensor electronics cannot go to the rails. Here, it is assumed that the supply voltage is minimum 5V. If the supply voltage is 5V -5% the negative swing would be from 2.5V to 0.5V still. But the positive swing would be from 2.5V to 4.25V giving asymmetry. If a bipolar current is to be measured, the negative swing is in fact reduced also for reasons of symmetry. Now, if the supply voltage is forced always to be within the positive tolerance, the swing is optimised. E.g. if the actual supply voltage tolerance is set to 5.125V+/− 2.4%, important mV's are gained. The swing may in fact be increased by over 10% enabling the gain to be increased by the same amount. Further, it should be emphasized that the 5V supply may be used for other purposes still even though the average voltage is now 5.125V or whatever value greater than or equal to 5V.

It is preferred, that the supply voltage for the transducer is placed in the center of the tolerance band.

Concerning the overall accuracy, an important goal is to simplify the conditioning circuitry between the current sensor and the A/D-converter on the control card. A single amplifier stage should be preferred for conditioning. And if possible, the sensor output should be used for a comparator-based hardware protection directly to obtain the best bandwidth by avoiding external amplifier stages. Hence, the internal gain of the current transducer is set by considering the transient overcurrent range for protection. And the control conditioning amplifier is used for increasing this low protection gain to obtain an adequate control current signal level before entering the A/D-converter. Those skilled in the art will know that the scheme in fact increases the control current measurement range of the current transducer at the same time.

A motor controller according to the invention may further comprise an A/D-converter which oversamples the output signal of the current transducer, whereby the instant of sampling can be hastened or delayed, hereby placing the instant of sampling in PWM zones, where supposedly no noise is present.

The invention can also be used in cases, where several current sensing devises are placed on the power card.

### BRIEF DESCRIPTION OF THE DRAWINGS

In the following a preferred embodiment of the invention is described by way of the figures in which:

FIG. 1 is a block diagram of a motor controller, where the method according to the invention is realised.

FIG. 2 is a circuit diagram of a preferred layout of the differential amplifier for conditioning the current signal from the power card.

FIG. 3 is a diagram showing a phase current and the corresponding PWM voltage.

FIG. 4 shows the appearance of a phase current when using long motor cables.

FIG. 5 shows the phase current of FIG. 4 after being measured and reestablished according to the method of the invention.

FIG. 6 shows an embodiment of the sampling strategy according to the invention.

### DETAILED DESCRIPTION OF THE PREFERRED EMBODIMENTS

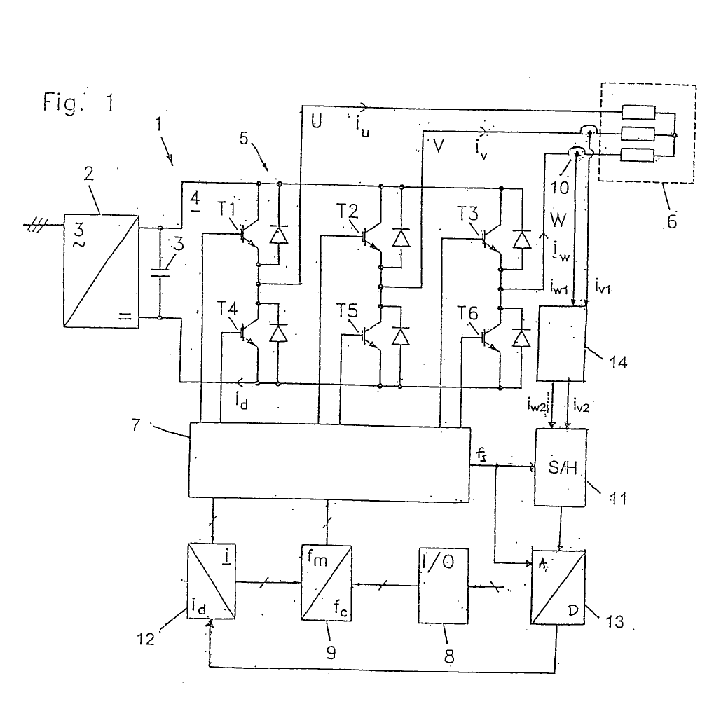

A frequency converter 1 shown in FIG. 1 consists of an uncontrolled rectifier 2 with intermediate circuit capacitor 3, which feeds a DC intermediate circuit 4 with an inverter bridge 5. The inverter bridge consists of controlled semiconductor switches T1, T2, T3, T4, T5 and T6, which by pulse width modulation transform the direct voltage of the intermediate circuit into a 3-phase alternating voltage on the output or phase conductors U, V, and W. In the embodiment shown, the semiconductor switches are transistors of the IGBT type (Insulated Gate Bipolar Transistor). As usual, freewheeling diodes are coupled in antiparallel with the transistors. The 3-phase output voltage U, V, W of the inverter is supplied to a load 6 in the form of a three-phase asynchronous motor.

The inverter bridge is controlled by a control circuit 7, which includes a pulse width modulator and a driver circuit for control of the transistors. For operation of the motor controller, this is provided with a user interface 8, which emits signals to a regulation and control unit 9.

The unit 9 functions as a regulator, which by the frequency f_{c} monitors the operational functions of the inverter, emitting any corrective signals which are transformed into the modulation frequency fₘ and transmitted to the pulse width modulator in the control circuit 7.

The applied phase voltages U, V, and W cause phase currents iᵤ, iᵥ and i_{w}, which are transformed via the inverter bridge to a resulting current i_{d} in the intermediate circuit. On two of the motor phases respectively, a magnetic current transducer 10 is placed, which converts the current in the phase windings to voltage signals i_{w1} and iᵥ₁ representing the currents. The signals are sent to a signal conditioning unit 14 and further on to a sample and hold unit 11, where sampling is performed at a sampling frequency fs. The sampled signals are led to an A/D converter 13 converting at the sample frequency. The digitalised phase current signals are passed on to a processor unit 12, which on the basis of the phase currents and data on the positions of the switches from the controller 7 calculates the three phase currents iᵤ, iᵥ and i_{w} in the form of a current vector i, which is made available to the regulating unit 9. Only two current transducers are used, as the current in the third phase U is calculated from the two currents in a known way.

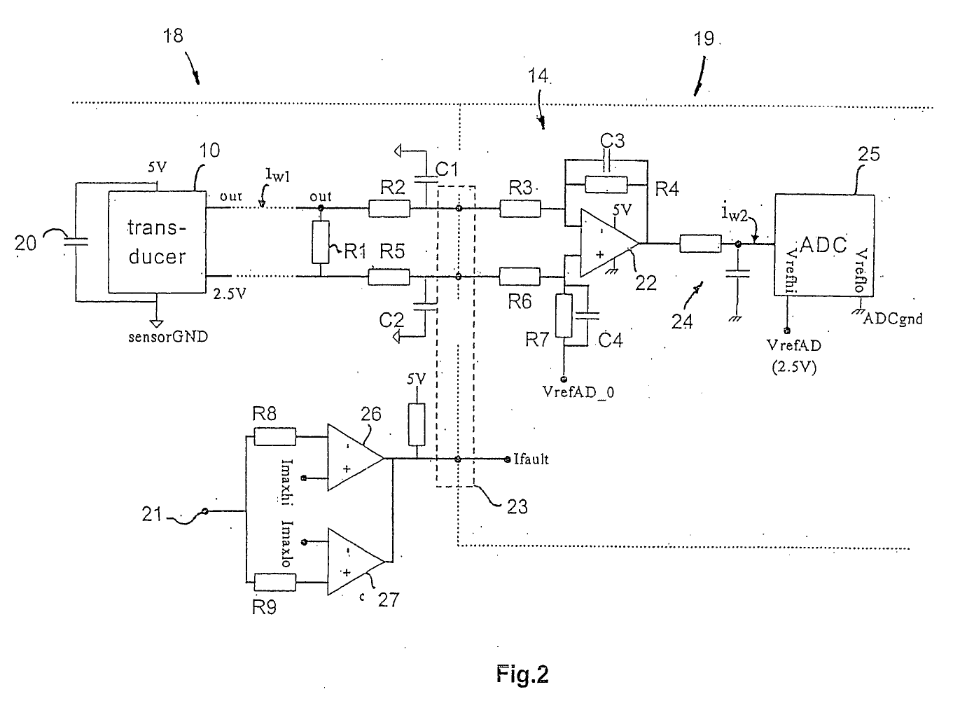

The hardware setup for transmitting the transducer signal from the power card to the control card is shown in FIG. 2. On the power card 18 the current transducer 10 is placed, which is fed from a voltage source 20. The internal gain of magnetic current transducers is usually set by choosing an appropriate number of primary turns in an internal signal transformer and by an external measurement resistor (R1). These are tuned to give a gain suited for the overcurrent range of the frequency converter. R1 is 30 ohm in the present example. The power card 18 and the control card 19 are electrically connected via connector 23. The signal i_{w1} is fed via connection 21 to a comparator bank (26,27,R8,R9) on the power card going low in case of an overcurrent incident. The incident is fed to the control card. The signal across the resistor (R1) is processed by a signal conditioning circuit 14 incorporating a differential amplifier 22 increasing the gain and adding an offset voltage VrefAD_{—}0 suited for the A/D-converter input voltage range of 3.3 V. VrefAD_{—}0 is 1.65 V in the present example. The differential amplifier stage is special in the way that the feedforward resistors R2, R5 and capacitors C1, C2 can be used to set the gain and filtering level from the power card passively even though the active amplifier is placed on the control card close to the A/D-converter 25. R2, R5 are each selected at 2 kohm and C1 and C2 at 1 nF. The feedforward resistors R3, R6 on the control card are used to lower the impact of noise originating from the parallel connector 23 interfacing the power and control card. More specific, the resulting gain A of the differential amplifier is calculated in the following way:
A =−R4/(R3+R2)

Thus, components placed on the power card and on the control card are used to influence on the gain of the differential amplifier 22.

The output of differential amplifier 22 is sent via antialiasing filter 24 to A/D converter 25, which incorporates a S/H circuit sampling the signal i_{w2}.

The main reason for using a differential amplification is, with reference to FIG. 2, the following. The voltage references sensorGND and ADCgnd should ideally be the same. But the parallel connector interfacing the power and control card may easily give some mV common-mode disturbance which instantly impacts the current signal if not differentially transmitted. As shown in FIG. 2, the differential signal is made by relating the output signal “out” (i_{w1}) of a first conductor to a voltage potential (2.5V) on a second conductor. At zero load current the output signal i_{w1} is 2.5V but ranges between 0.5 and 4.5V during load. In principle, the signal from the transducer can be led single-ended out, but this will cause an undesired high sensitivity towards noise which again causes a lowered SNR. Thus it is preferred, that the single-ended transmission path is as short as possible, which in FIG. 2 is the path from the output of differential amplifier 22 to A/D-converter 25.

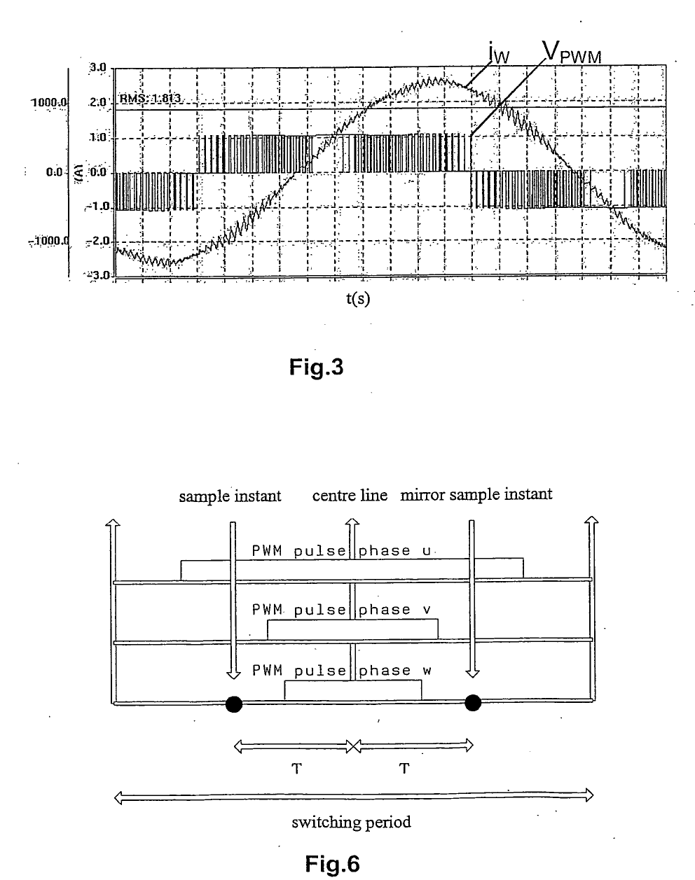

A typical phase current (e.g.i_{w}) sensed by the current transducer 10 is shown in FIG. 3 along with a phase-phase PWM output voltage V_{PWM}. The PWM switching frequency is 4.5 kHz. The phase current contains a ripple current (higher harmonics) related to the digital nature of the output voltage fed to the 3-phase induction motor 6 loading the motor controller. The ripple current is an undesirable disturbance. The parameter of interest is the fundamental output current when controlling the motor. Additionally to the PWM generated ripple current and as mentioned earlier, noise is superimposed on the current due to internal switchings in the current transducer and due to noise picked up during the signal transmission to the A/D-converter. Doing the oversampling with an even number of samples during a switching period, summing the samples and then averaging them by dividing with the number of samples minimizes the impact of the noise. FIG. 6 gives a simultaneous view of the PWM pulse shapes on the motor phase U,V and W during a switching period. At the shown “sample instant” the three phase currents are sampled simultaneously. In the middle of the switching period a centre line is shown, and the left and right-side sample instants are preferably placed symmetrically in pairs around this centre line. Thus, a mirror sample is taken a time T from the centre line, which corresponds to the same time distance from the first sample instant to the centre line. Only a single “sample instant” and its mirror are shown. Several evenly distributed sample instants are of course required to obtain a satisfactory effect of the oversampling.

In FIG. 1, circuit blocks 7,8,9,11,12 and 13 are implemented in a Digital Signal Processor of the type C2407xx by manufacturer Texas Instruments. The DSP is programmed to run a space-vector PWM at a switching frequency of 3030 Hz. The A/D converter 13 of the DSP is setup to sample each of the two phase current signals at a rate of 5 μs each. Hence, 66 samples are available per current signal per switching period to calculate the average current. A 400 Vrms, 3 kW induction motor was fed via a screened motor cable of 150 m giving heavy capacitive charging current each time the frequency converter is switched. To exclude “bad” current samples disturbed by the capacitive charging of the motor cable etc, a given sample is sorted out if it is within a given time interval from the last PWM switching according to the inventive method. Sorting out is done by the controller 7 using processor unit 12 (FIG. 1), where a register holds the digitalized data. Controller 7 has access to this register and conditions the data by sorting out digital samples that are sampled in a predefined region around a switching of a transistor. E.g. if a sample is taken on current i_{w} shortly after T1 has been opened, then this sample will be skipped. The period in which no samples are accepted equals a blanking time. The blanking time depends on parameters like the response time of the switching transistors, the switching frequency and especially on the length of the motor cables.

Prior to normal operation of the motor controller, an initialization phase may be activated depending on the type of current transducer. More specific, the output signals of magnetic current transducers 10 are sampled sequentially during a first period of time, while the transducers are unloaded by current, i.e. currents i_{w} and iᵥ are zero. By detecting the offset ripple frequency of each current transducer the best compromise of the sampling frequency during a second period of time, which is the normal operation period of the motor controller is derived by the controller 7. In other words, an adaptive sampling frequency is achieved. In this embodiment, the sampling frequency is 200 kHz, i.e. much higher than the PWM switching frequency of 3030 Hz.

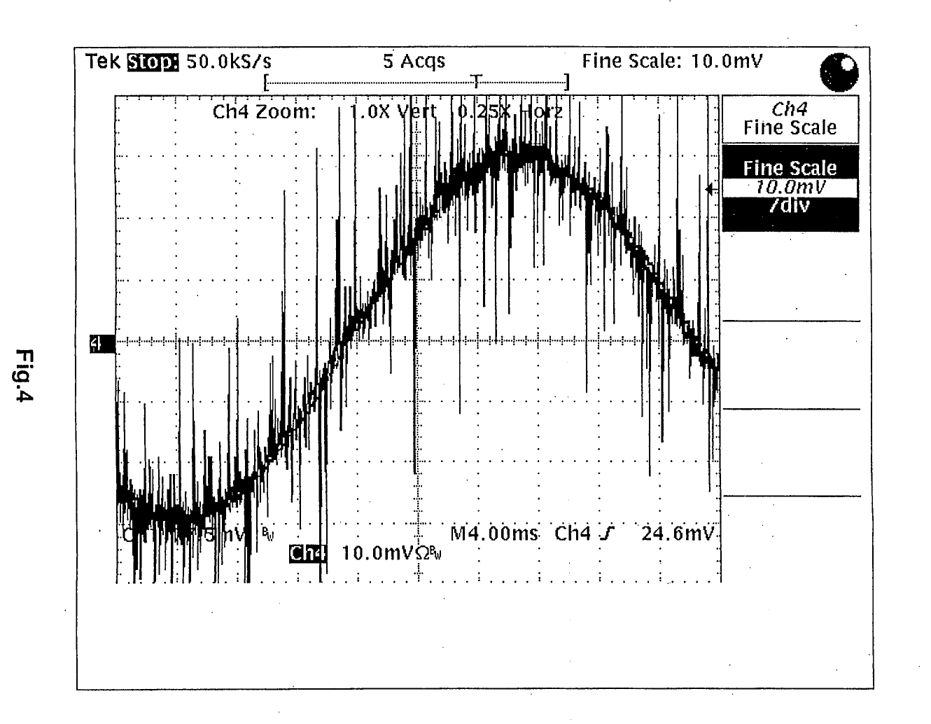

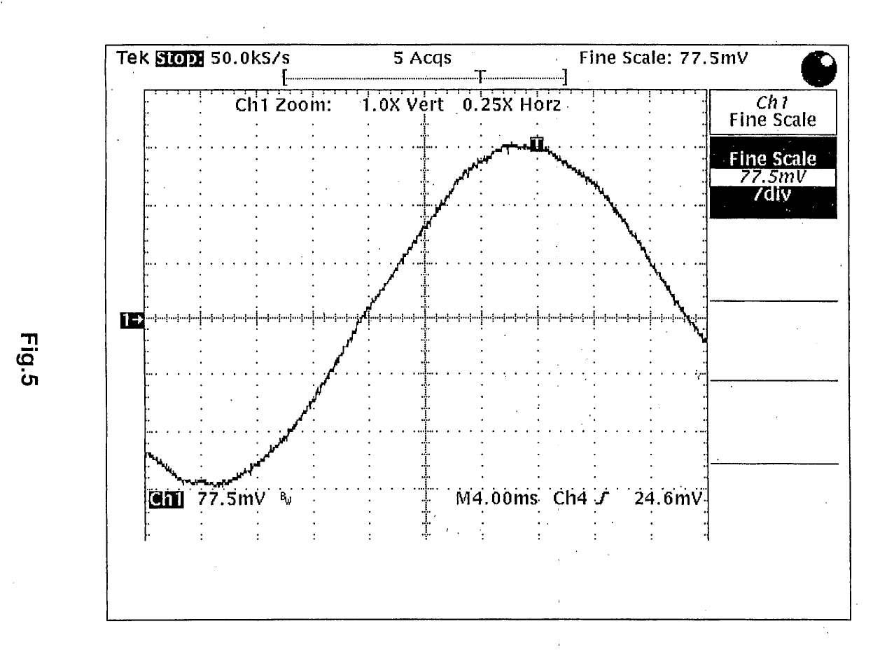

FIG. 4 shows the phase current i_{w} at a fundamental motor frequency of 21.5 Hz, approximately half the nominal speed. It contains current ripple and the high-frequency, capacitive cable currents causing the high spikes. The length of the motor cables is 150 m. The signal in FIG. 4 corresponds approximately to the voltage signal i_{w1} fed to the conditioning block 14. FIG. 5 shows the current of FIG. 4 after being measured according to the method of the invention. More specific, FIG. 5 shows the calculated average current per switching period put out on a DA converter channel (not shown) by the DSP (stair-case curve). Relative to the rated current of the 3 kW motor the phase current is sensed with a 1% accuracy. The number excludes the normal gain and offset errors of the magnetic current transducer 10 specified in the data sheet to validate the quality of the inventive method specific. Taking into account that an analog signal i_{w1} of some 100 mV was transferred over a distance of 30 cm printed circuit board-track and flat-cable this is a good result.

Compared to a single-sample digital current with a worst-case peak transmission error of say 10 mV this is at least an improvement of a factor of four.

1-18. (canceled)

19. A method for measuring current in a motor controller comprising the steps of:
employing switching of power semiconductors, a current being sensed by a current sensing device placed on a motor phase;
generating an output signal, the output signal (i_{w1}, iᵥ₁) being transmitted to a receiving unit;
sampling with an oversampling frequency (fₛ) during a switching period of the power semiconductors, digitally filtering said samples to maintain symmetry of the samples with respect to a centre line of the switching period;
and calculating an average value of the samples.

20. A method according to claim 19, wherein the step of digitally filtering includes hastening and delaying the originally evenly-distributed sample positions to be in quiet PWM zones.

21. A method according to claim 19, wherein the step of digitally filtering includes sorting out samples known to be disturbed as well as sorting out non-disturbed samples.

22. A method according to claims 20, wherein a second average is calculated within the actual switching period using samples from the last half of the preceeding switching period and samples from the first half of the actual switching period to obtain two current values per switching period.

23. A method according to claim 19, wherein the current sensing device is a unipolar magnetic current sensor.

24. A method according to claim 19, wherein that the sampling frequency (fₛ) is adjusted according to the result of an initialisation test on one or more current sensing devices in a current free period.

25. A method according to claim 19, wherein the output signal is transmitted differentially.

26. A motor controller comprising a power card and a control card, a current sensing device placed on the power card for generating an output signal to the control card, the output signal (i_{w1}, iᵥ₁) being transmitted to an amplifier placed on the control card, the amplifier having a gain determined by components mounted on the power card and components mounted on the control card.

27. A motor controller according to claim 26 wherein the amplifier is a differential amplifier and that the output signal (i_{w1}, iᵥ₁) is differentially transmitted.

28. A motor controller according to claim 27, wherein the differential amplifier is a single stage ampliflier having a fixed gain determined by the components on the control card, and that the fixed gain is changeable with the components mounted on the power card.

29. A motor controller according to claim 27, wherein analog filtering degree of the differential amplifier may be set on the power card independent of an internal bandwidth of the current sensing device.

30. A motor controller according to claim 26, wherein the current sensing device is a magnetic current transducer fed with a supply voltage.

31. A motor controller according to claim 30, wherein the supply voltage of a unipolar magnetic current transducer is set to be at least two times larger than an internal voltage reference of the transducer.

32. A motor controller according to claims 30, wherein the supply voltage of a unipolar current transducer is restricted to be in the positive/upper tolerance band of the tolerance on the transducer supply voltage.

33. A motor controller according to claim 32, wherein the actual supply voltage for the current transducer is centered within the upper supply voltage tolerance band of the unipolar current transducer.

34. A motor controller according to claim 30, wherein the magnetic current transducer on the power card gives the output signal a gain which enables the output signal to be used for overcurrent protection of the motor controller.

35. A motor controller according to claim 26, further comprising an A/D-converter programmed to oversample the output signal over the switching period, while hastening and delaying the originally evenly-distributed sample positions to be in quiet PWM zones.

36. A motor controller according to claim 19, wherein several current sensing devices are placed on the power card.
